(19) United States
(12) Patent Application Publication
(10) Pub. No.: US 2026/0214854 A1
(43) Pub. Date: Jul. 23, 2026

(54) SYSTEMS AND METHODS FOR EVAPORATIVE COOLING

(71) Applicant: Toyota Motor Engineering & Manufacturing North America, Inc., Plano, TX (US)

(72) Inventor: Shailesh N. Joshi, Ann Arbor, MI (US)

(73) Assignee: Toyota Motor Engineering & Manufacturing North America, Inc., Plano, TX (US)

(21) Appl. No.: 19/034,025

(22) Filed: Jan. 22, 2025

(51) Int. Cl. H05K 7/20

(52) U.S. Cl. CPC H05K 7/20336; H05K 7/20327

(57) ABSTRACT

Cooling assembly for cooling a heat generating component. One embodiment of the cooling assembly may include a hydrogel layer on a thermally conductive substrate, the hydrogel layer including a plurality of macro pores and a micro pore region including a plurality of micro pores; a manifold including: one or more liquid inlet ports, a liquid channel operable for receiving a cooling liquid through the one or more liquid inlet ports, and a plurality of liquid outlets operable for transporting the cooling liquid from the liquid channel to the hydrogel layer; and a vapor chamber positioned between the thermally conductive substrate and the manifold, the vapor chamber including one or more vapor outlet ports and operable for transporting vapor from the plurality of macro pores on the hydrogel layer to the one or more vapor outlet ports; wherein the plurality of micro pores change in size based on temperature.

### TECHNICAL FIELD

Embodiments described herein generally relate to cooling systems, more particularly, evaporative cooling systems.

### BACKGROUND

Electronic devices (e.g., power electronic devices) such as insulated-gated bipolar transistors (IGBTs) and metal-oxide-semiconductor field-effect transistors (MOSFETs) generate significant heat fluxes that need to be removed to ensure that the power electronic devices operate below their maximum operating temperatures. Conventionally, heat sinks and liquid-based coolers are frequently used as cooling devices for such power electronic devices. As the technology and prevalence of power electronic devices continue to evolve and expand, improved systems, apparatuses, and methods for cooling the power electronic devices are desired.

### SUMMARY

Systems, apparatuses, and methods for evaporative cooling are described. One embodiment of a cooling assembly includes a hydrogel layer on a thermally conductive substrate, the hydrogel layer including a plurality of macro pores and a micro pore region including a plurality of micro pores; a manifold including: one or more liquid inlet ports; a liquid channel operable for receiving a cooling liquid through the one or more liquid inlet ports; and a plurality of liquid outlets operable for transporting the cooling liquid from the liquid channel to the hydrogel layer; and a vapor chamber positioned between the thermally conductive substrate and the manifold, the vapor chamber including one or more vapor outlet ports and operable for transporting vapor from the plurality of macro pores on the hydrogel layer to the one or more vapor outlet ports; and wherein the plurality of micro pores change in size based on temperature.

In another embodiment, an electronic assembly includes an electronic device; and a cooling assembly for cooling the electronic device, the cooling assembly including: a hydrogel layer on a thermally conductive substrate, the hydrogel layer including a plurality of macro pores and a micro pore region including a plurality of micro pores; a manifold including: one or more liquid inlet ports; a liquid channel operable for receiving a cooling liquid through the one or more liquid inlet ports; and a plurality of liquid outlets operable for transporting the cooling liquid from the liquid channel to the hydrogel layer; and a vapor chamber positioned between the thermally conductive substrate and the manifold, the vapor chamber including one or more vapor outlet ports and operable for transporting vapor from the plurality of macro pores on the hydrogel layer to the one or more vapor outlet ports; and wherein the plurality of micro pores change in size based on temperature.

In yet another embodiment, a vehicle includes an electric motor; and an electronic assembly including an electronic device and a cooling assembly for cooling the electronic device, wherein the cooling assembly includes: a hydrogel layer on a thermally conductive substrate, the hydrogel layer including a plurality of macro pores and a micro pore region including a plurality of micro pores; a manifold including: one or more liquid inlet ports; a liquid channel operable for receiving the cooling liquid through the one or more liquid inlet ports; and a plurality of liquid outlets operable for transporting the cooling liquid from the liquid channel to the hydrogel layer; and a vapor chamber positioned between the thermally conductive substrate and the manifold, the vapor chamber including one or more vapor outlet ports and operable for transporting vapor from the plurality of macro pores on the hydrogel layer to the one or more vapor outlet ports; and wherein the plurality of micro pores change in size based on temperature.

These and additional features provided by the embodiments of the present disclosure will be more fully understood in view of the following detailed description, in conjunction with the drawings.

### BRIEF DESCRIPTION OF THE DRAWINGS

The embodiments set forth in the drawings are illustrative and exemplary in nature and not intended to limit the disclosure. The following detailed description of the illustrative embodiments can be understood when read in conjunction with the following drawings, where like structure is indicated with like reference numerals and in which:

FIG. 1 illustrates a perspective view of an example cooling assembly, according to embodiments described herein;

FIG. 2 illustrates a cross-sectional view of an example cooling assembly, according to embodiments described herein;

FIG. 3 illustrates a cross-sectional view of an example cooling assembly, according to embodiments described herein;

FIG. 4 illustrates a cross-sectional view of an example hydrogel layer of the example cooling assembly of FIGS. 2 and 3, according to embodiments described herein;

FIGS. 5A and 5B illustrate partial cross-sectional views of the example hydrogel layer of FIG. 4, according to embodiments described herein; and

FIG. 6 schematically depicts a vehicle having an electric motor electrically coupled to an electronics module having the example cooling assembly, according to embodiments described herein.

### DETAILED DESCRIPTION

A general technical problem associated with operating electronic devices (e.g., power electronic devices) such as insulated-gated bipolar transistors (IGBTs) and metal-oxide-semiconductor field-effect transistors (MOSFETs) is related to heat (e.g., heat flux) that the power electronic devices generate, for example, when operating. If the generated heat flux is not handled properly, a power electronic device may overheat and result in various issues, such as undesired electrical behaviors resulting in unexpected slowdown or shutdown of the power electronic device. Moreover, electrical components within such power electronic device may be damaged, potentially leading to a complete failure of the power electronic device, data loss, and/or hazardous events such as fire or explosion. Thus, the heat flux generated by the power electronic device needs to be removed to ensure that the power electronic device operates properly, such as below its maximum operating temperature. Conventionally, heat sinks and liquid-based coolers were used as cooling devices for power electronic devices.

An evaporative cooler is an example of a cooling device, where a liquid such as a cooling liquid is introduced into a cooling chamber, is heated by a heat generating component or device (e.g., a power electronic device), evaporates into a vapor, and is removed from the cooling chamber to be condensed and re-introduced into the cooling chamber. For example, the liquid may be introduced into the cooling chamber by a capillary structure, such as a wick. However, conventional cooling devices, including conventional evaporative coolers, are not tunable between different heat flux situations, such as low and high heat flux situations. For example, a constant level of cooling may not be effective in varying heat flux situations, where the effect of cooling may decrease as the level of heat flux increases.

Some cooling devices such as the evaporative cooler may utilize, for example, a pump to vary a rate of a cooling liquid introduced into a cooling chamber to adjust the level of cooling effected by the cooling liquid. However, such a cooling device may not be very efficient in varying heat flux situations, where for example, an increased level of heat flux may require the pump to increase its pumping rate, resulting in an increase in power demand for the pump.

Embodiments of the present disclosure improve how a heat generating component may be cooled. Particularly, certain embodiments of the present disclosure provide a two-phase cooling assembly that includes a hydrogel layer having a porous hydrogel as a tunable capillary structure, where the cooling assembly may be an evaporative cooler that is tunable by the use of the hydrogel. The hydrogel includes a plurality of macro pores and a micro pore region, where the micro pore region includes a plurality of micro pores. The macro pores and the micro pores refer to different groups of pores on the hydrogel, and do not necessarily indicate the size (e.g., absolute or relative) of each pore. At a given temperature such as below a threshold temperature, the macro pores may be larger than the micro pores (e.g., in diameter or volume of the void defined by each pore, etc.). In some embodiments, when a temperature of the hydrogel changes from a first temperature lower than a threshold temperature (e.g., a lower critical solution temperature (LCST)) to a second temperature at or higher than the threshold temperature, the micro pores may increase in size based on such change in temperature. The enlarged micro pores may receive an additional amount of cooling liquid by a capillary action. The additional amount of cooling liquid may evaporate through the macro pores to cool a heat generating component as the temperature of the heat generating component increases, such as beyond the threshold temperature. By utilizing such hydrogel, embodiments of the present disclosure provide a two-phase evaporative cooler that can provide two levels of cooling depending on the level of generated heat flux.

When the level of generated heat flux does not reach a threshold level (e.g., corresponding to the threshold temperature described above), certain embodiments of the present disclosure may provide cooling that does not utilize the additional amount of cooling liquid to be received within the enlarged micro pores as described above. When the level of generated heat flux reaches or exceeds the threshold level, certain embodiments of the present disclosure may effect an increased amount of cooling based on the additional amount of cooling liquid received within the enlarged micro pores. Thus, the increased amount of cooling liquid that effects the cooling effect may rely on the varied behavior of the hydrogel, mitigating a need for, for example, an increased load on a pump that pumps the cooling liquid through the evaporative cooler. Accordingly, various embodiments of the present disclosure result in technical benefits and advance the state of the art in cooling a heat generating component by making the evaporative cooler more efficient and mitigating the need for an increased power demand on a cooling assembly.

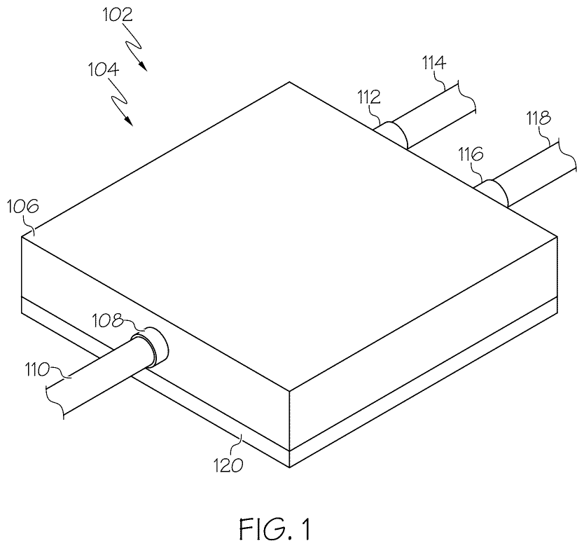

Referring now to FIG. 1, an example electronic assembly 102 is illustrated in a perspective view. The example electronic assembly 102 includes an electronic device 120 coupled to a cooling assembly 104. The cooling assembly 104 is operable to remove heat generated by the electronic device 120, or in some cases multiple electronic devices 120. The cooling assembly 104 ensures that the electronic device 120 operates below its maximum operating temperature. Embodiments disclosed herein are not limited to any particular electronic device 120. In some cases, the electronic device 120 may be and/or include a heat generating component that is not an electronic device. Thus, the cooling assembly 104 may be used to cool any type of heat generating component.

Non-limiting examples of the electronic device 120 include MOSFETs, IGBTs, thyristors, power transistors, power diodes, and the like. As a non-limiting example, the electronic devices 120 described herein may be components of an inverter circuit of an electrified vehicle (e.g., a fully electric vehicle, a hybrid vehicle, or a plug-in hybrid vehicle) to convert direct current (DC) voltage to alternating current (AC) for powering an electric motor of the electrified vehicle. It should be understood that the electronics assemblies 102 described herein may be utilized in other applications as well.

As illustrated, the cooling assembly 104 includes a housing 106 having a liquid inlet port 108 for providing a cooling liquid through a liquid inlet line 110 into an enclosure defined by the housing 106. The housing 106 also includes a liquid outlet port 112 for removing a bypass cooling liquid through a liquid outlet line 114. Moreover, the housing 106 includes a vapor outlet port 116 for removing vapor through a vapor outlet line 118. It should be understood that more than one liquid inlet port 108, more than one liquid outlet port 112, and/or more than one vapor outlet port 116 may be provided. The liquid inlet port 108, the liquid outlet port 112, and/or the vapor outlet port 116 may be individually disposed on a side surface, a top surface, or a bottom surface of the housing 106, or in any other manner as would be apparent to those skilled in the art. In some embodiments, the liquid outlet port 112 and the vapor outlet port 116 may be combined into a single outlet port that moves both the bypass cooling liquid and the vapor from the housing 106. In some embodiments, the vapor may be condensed and re-circulated back to the liquid inlet line 110 through the vapor outlet line 118.

Reference will now be made in detail to cooling assemblies (e.g., cooling assembly 104), and more particularly, to embodiments that control the level of cooling based on change in size of a plurality of micro pores on a hydrogel layer to achieve improved cooling efficiency.

Certain embodiments described herein provide a two-phase evaporative cooler, where a cooling liquid is introduced into a manifold having a plurality of liquid outlets (which may be referred to as a plurality of manifold tubes) extending into a chamber to provide the cooling liquid in the chamber. The plurality of liquid outlets may be fluidly coupled to a hydrogel layer that acts as a wick to pull the cooling liquid by capillary force. Hydrogel is a material having a micro pore network that changes in response to the application of heat. For example, when a heat generating component or device heats the hydrogel above a threshold temperature (e.g., lower critical solution temperature (LCST)), the micro pores open up by getting larger. This allows more cooling liquid to be provided to the hydrogel. In this manner, the capillary force and the amount of cooling liquid drawn into the chamber can be adjusted based on temperature. The cooling liquid present within the chamber may be evaporated by the heat generating component or device, turned into a vapor, and then exit the chamber (e.g., toward a condenser). Accordingly, embodiments of the present disclosure provide a tunable evaporative cooler that is tuned by the use of a hydrogel having a plurality of micro pores that change in size (e.g., opening when above the LCST and closing below the LCST).

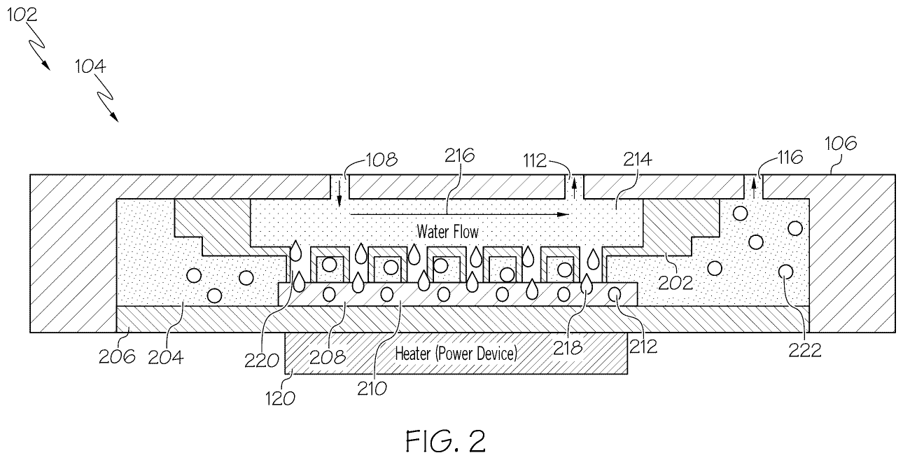

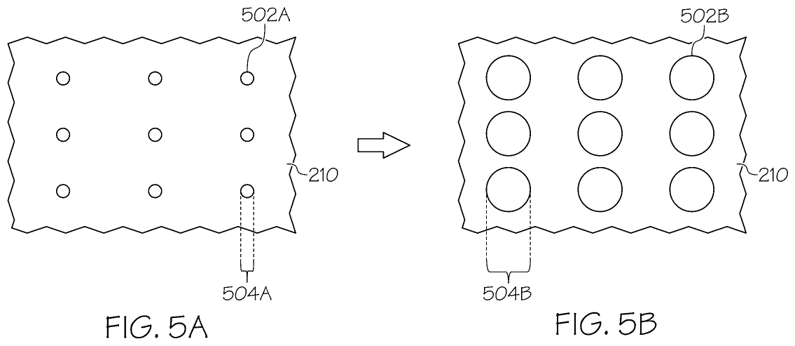

Referring now to FIG. 2, a cross-sectional view of an example cooling assembly 104 (of the electronic assembly 102) is illustrated. The cooling assembly 104 (e.g., within the housing 106) includes a manifold 202 disposed within a vapor chamber 204 (which is a type of chamber and may be referred to as a cooling chamber). Moreover, the housing 106 includes a thermally conductive substrate 206 that may be coupled to (e.g., in contact with) the electronic device 120 to receive the heat flux generated by the electronic device 120. The thermally conductive substrate 206 may be coupled to (e.g., in contact with) a hydrogel layer 208 having a micro pore region 210 and a plurality of macro pores 212. The micro pore region 210 includes a plurality of micro pores, and is described further herein with reference to FIGS. 5A and 5B.

The manifold 202 defines a liquid channel 214 that is fluidly coupled to the liquid inlet port 108. The manifold 202 also defines a plurality of liquid outlets 220. The plurality of liquid outlets 220 are fluidly coupled to the liquid inlet port 108 through the liquid channel 214 for receiving a cooling liquid 216 (e.g., water or any other type of cooling liquid) and is operative to introduce a portion 218 of the cooling liquid 216 toward the hydrogel layer 208. The plurality of liquid outlets 220 may be operable for transporting the cooling liquid 216 from the liquid channel 214 to the hydrogel layer 208. The liquid channel 214 may be operable for receiving the cooling liquid 216 through the liquid inlet port 108. In some embodiments, the manifold 202 may be thermally conductive, such as to effect an additional amount of cooling by enabling heat transfer through the cooling liquid 216 in the liquid channel 214 being transported out of the liquid channel 214 via the liquid outlet port 112.

The cooling liquid 216 is received from the liquid inlet port 108 and flows through the liquid channel 214. Cooling liquid 216 flowing through the liquid channel 214 enters the plurality of liquid outlets 220, such as by capillary force. As described further herein, when the temperature of the electronic device 120 changes to cause a change in the generated heat flux, the plurality of micro pores on the micro pore region 210 may increase in size. The change in the generated heat flux may correspond to a change in temperature from a first temperature below a threshold temperature such as the LCST to a second temperature at or above the threshold temperature. Before the change in temperature, the surface tension of the cooling liquid 216 may not allow the cooling liquid 216 to enter the plurality of micro pores. After the change in temperature, some of the cooling liquid 216 (e.g., the portion 218) may be received within the plurality of micro pores. The portion 218 of the cooling liquid 216 received within the plurality of micro pores may be evaporated into vapor 222 by the heat generated by the electronic device 120.

The vapor 222 may exit the hydrogel layer 208 through the plurality of macro pores 212 and into the vapor chamber 204. The vapor chamber 204 may be positioned between the thermally conductive substrate 206 and the manifold 202. For example, the vapor chamber 204 may be positioned between the hydrogel layer 208 and the manifold 202. The vapor chamber 204 may include the vapor outlet port 116. The vapor chamber 204 may be operable for transporting the vapor 222 from the plurality of macro pores 212 on the hydrogel layer 208 to the vapor outlet port 116. The vapor 222 in the vapor chamber 204 may exit the vapor chamber 204 via the vapor outlet port 116. The bypass portion of the cooling liquid 216 (e.g., the portion that does is not transported to the hydrogel layer 208) exits the liquid channel 214 via the liquid outlet port 112. The added amount of cooling liquid 216 within the plurality of enlarged micro pores on the hydrogel layer 208 may enable an increased level of heat transfer to effect an increased level of cooling on the electronic device 120.

In certain embodiments, the hydrogel layer 208 may include or be made of a hydrophobic material and a hydrophilic material. In some embodiments, the hydrogel layer 208 may include or be made of Poly(N-isopropylacrylamide) (PNIPAM) hydrogel, which is a three-dimensional (3D) crosslinked polymer with thermoresponsive properties. Other types of hydrogel may also be used to make up the hydrogel layer 208.

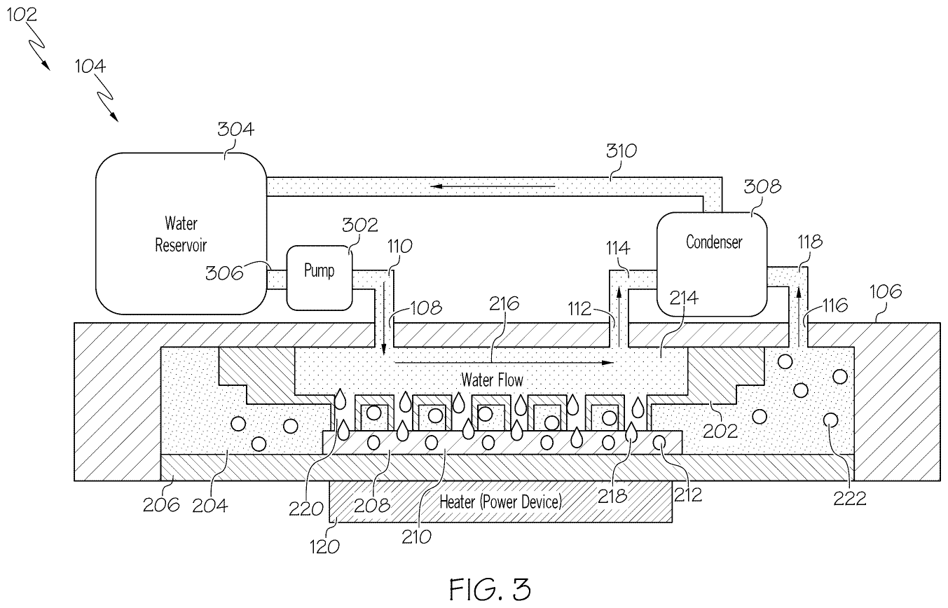

Referring now to FIG. 3, certain embodiments of the electronic assembly 102 (and/or the cooling assembly 104) may include a pump 302 in addition to the components described herein with reference to FIG. 2. The pump 302 may be connected to a reservoir 304 (e.g., a cooling liquid reservoir or a water reservoir) via a first liquid line 306. The pump 302 may be configured to draw the cooling liquid 216 from the reservoir 304 to introduce the cooling liquid 216 to the liquid inlet port 108 via a liquid inlet line 110. Furthermore, some embodiments of the electronic assembly 102 (and/or the cooling assembly 104) may include a condenser 308. The condenser 308 may collect the bypass cooling liquid from the liquid outlet port 112 via a liquid outlet line 114. Moreover, the condenser 308 may collect the vapor 222 from the vapor outlet port 116 via a vapor outlet line 118. The condenser 308 may be configured to convert the vapor 222 received via the vapor outlet line 118 into a liquid state to be transported to the reservoir 304 via a second liquid line 310.

It is contemplated that the electronic assembly 102 and/or the cooling assembly 104 may further include a programmable controller configured to control the pump 302 for controlling the rate of flow of the cooling liquid 216.

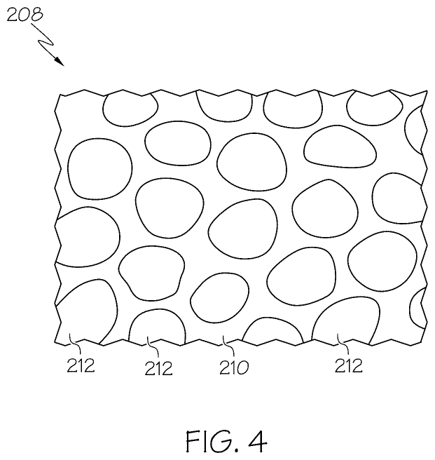

Referring now to FIG. 4, a cross-sectional view of a portion of the hydrogel layer 208 is illustrated. As illustrated, the hydrogel layer 208 includes micro pore region 210 and a plurality of macro pores 212. As described herein with reference to FIG. 2, the micro pore region 210 includes a plurality of micro pores. Additional details regarding the micro pore region 210 and the plurality of micro pores are described with reference to FIGS. 5A and 5B.

Referring to FIGS. 5A and 5B, the hydrogel layer 208 includes micro pore region 210. Within the micro pore region 210, the hydrogel layer 208 includes a plurality of micro pores 502A, 502B (which may be collectively referred to as a plurality of micro pores 502). As illustrated in FIG. 5A, each micro pore 502A may have a first size corresponding to a first diameter 504A at a temperature below a threshold temperature (e.g., LCST). When a change in temperature is introduced to the hydrogel layer 208 (e.g., by the heat generated by a heat generating component as described here with reference to FIG. 2), the micro pore 502A may increase in size and become the micro pore 502B illustrated in FIG. 5B. As illustrated in FIG. 5B, the micro pore 502B may be enlarged to have a second size corresponding to a second diameter 504B at a temperature at or above the threshold temperature. For example, the micro pore 502B may be large enough to receive the cooling liquid 216 (e.g., the portion 218) via capillary action. The cooling liquid received within the micro pore 502B may be evaporated by the heat generated by a heat generating component (e.g., electronic device 120, as described herein with reference to FIG. 2) and turned into vapor 222 that is released from the hydrogel layer 208 through the plurality of macro pores 212 (of FIG. 2).

In certain embodiments, each micro pore 502A may be a 5-10 nanometer (nm) pore, for example, when its temperature is below a threshold temperature (e.g., LCST). For example, the first diameter 504A at a temperature below the LCST may be about 5-10 nm. In some embodiments, each micro pore 502B may be a 10-50 micrometer (μm) pore, for example, when its temperature is at or above a threshold temperature (e.g., LCST). For example, the second diameter 504B at a temperature at or above the LCST may be about 10-50 μm. In certain embodiments, the diameter values (e.g., 504A, 504B) may be specific to a type of material included in the hydrogel layer 208, such as PNIPAM hydrogel. In some embodiments, the LCST associated with the hydrogel layer 208 may be tunable and may be about 25-80 degrees Celsius (° C.).

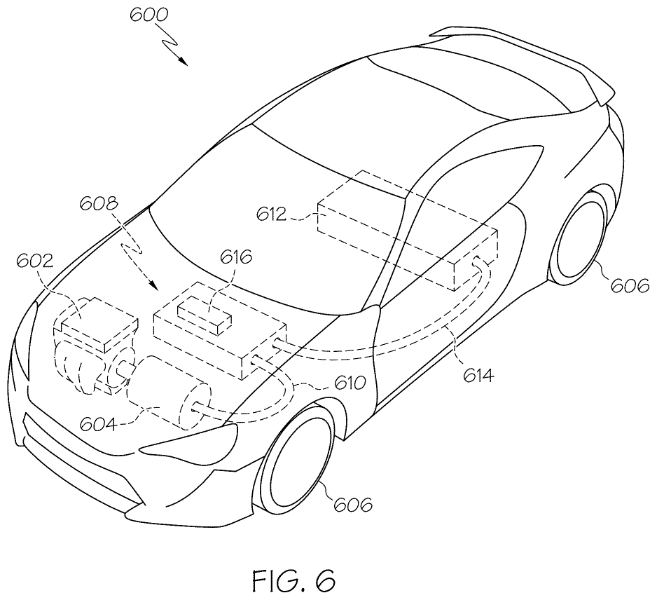

As stated above, the electronic assembly 102 having the cooling assembly 104 described herein may be incorporated into larger electronic device (e.g., power electronic device or circuits), such as inverter and/or converter circuits of an electrified vehicle. The electrified vehicle may be a hybrid vehicle, a plug-in hybrid vehicle, a fully electric vehicle, or any vehicle that utilizes an electric motor. Referring now to FIG. 6, a vehicle 600 configured as a hybrid vehicle or a plug-in hybrid vehicle is schematically illustrated. The vehicle 600 generally includes a gasoline engine 602 and an electric motor 604, both of which are configured to provide rotational movement to the wheels 606 of the vehicle 600 to propel the vehicle 600. A power electronic circuit 608 is electrically coupled to electric motor 604 (for example, by conductors 610). The power electronic circuit 608 may be configured as an inverter and/or a converter circuit that provides electrical power to the electric motor 604. The power electronic circuit 608 may in turn be electrically coupled to a power source, such as a battery pack 612 (for example, by conductors 614). The power electronic circuit 608 includes one or more electronics modules 616 (e.g., an electronic assembly 102) having the cooling assembly 104, as described above.

As illustrated above, various embodiments for cooling a heat generating component are disclosed. It would be apparent to one of ordinary skill in the art that, while certain embodiments are described with respect to cooling a part of an electrified vehicle, such as an electric motor, embodiments of the present disclosure can cool any heat generating component in any context without departing from the spirit and the scope of the present disclosure. Embodiments of the present disclosure provide technical benefits and advance the state of the art in cooling a heat generating component. As described herein, utilizing a hydrogel to provide a two-phase cooling system mitigates the need for additional pumping for evaporative cooling systems, thereby increasing efficiency and reducing power consumption.

Having described the subject matter of the present disclosure in detail and by reference to specific embodiments thereof, it is noted that the various details disclosed herein should not be taken to imply that these details relate to elements that are essential components of the various embodiments described herein, even in cases where a particular element is illustrated in each of the drawings that accompany the present description. Further, it will be apparent that modifications and variations are possible without departing from the scope of the present disclosure, including, but not limited to, embodiments defined in the appended claims. More specifically, although some aspects of the present disclosure are described herein as advantageous, it is contemplated that the present disclosure is not necessarily limited to these aspects.

It is noted that recitations herein of a component of the present disclosure being “configured” or “programmed” in a particular way, to embody a particular property, or to function in a particular manner, are structural recitations, as opposed to recitations of intended use. More specifically, the references herein to the manner in which a component is “configured” or “programmed” denotes an existing physical condition of the component and, as such, is to be taken as a definite recitation of the structural characteristics of the component.

It is noted that one or more of the following claims utilize the term “wherein” as a transitional phrase. For the purposes of defining the present disclosure, it is noted that this term is introduced in the claims as an open-ended transitional phrase that is used to introduce a recitation of a series of characteristics of the structure and should be interpreted in like manner as the more commonly used open-ended preamble term “comprising.”

It is noted that the singular forms “a,” “an” and “the” include plural referents unless the context clearly dictates otherwise. Thus, for example, reference to “a” component includes aspects having two or more such components, unless the context clearly indicates otherwise.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

All numerical ranges herein expressed in the format “from X to Y” are to be interpreted as including the endpoints X and Y and all numbers between the endpoints.

The order of execution or performance of the operations in examples of the disclosure illustrated and described herein is not essential, unless otherwise specified. That is, the operations may be performed in any order, unless otherwise specified, and examples of the disclosure may include additional or fewer operations than those disclosed herein. For example, it is contemplated that executing or performing a particular operation before, contemporaneously with, or after another operation is within the scope of aspects of the disclosure.

While particular embodiments and aspects of the present disclosure have been illustrated and described herein, various other changes and modifications can be made without departing from the spirit and scope of the disclosure. Moreover, although various aspects have been described herein, such aspects need not be utilized in combination. Accordingly, it is therefore intended that the appended claims cover all such changes and modifications that are within the scope of the embodiments shown and described herein.

It should now be understood that embodiments disclosed herein includes systems, apparatuses, and methods for cooling a heat generating component. It should also be understood that these embodiments are merely exemplary and are not intended to limit the scope of this disclosure.

What is claimed is:

1. A cooling assembly, comprising:
a hydrogel layer on a thermally conductive substrate, the hydrogel layer comprising a plurality of macro pores and a micro pore region comprising a plurality of micro pores;
a manifold comprising:
one or more liquid inlet ports;
a liquid channel operable for receiving a cooling liquid through the one or more liquid inlet ports; and
a plurality of liquid outlets operable for transporting the cooling liquid from the liquid channel to the hydrogel layer; and
a vapor chamber positioned between the thermally conductive substrate and the manifold, the vapor chamber comprising one or more vapor outlet ports and operable for transporting vapor from the plurality of macro pores on the hydrogel layer to the one or more vapor outlet ports; and
wherein the plurality of micro pores change in size based on temperature.

2. The cooling assembly of claim 1, wherein the plurality of micro pores increase in size based on a temperature change from a first temperature lower than a threshold temperature to a second temperature at or higher than the threshold temperature.

3. The cooling assembly of claim 1, wherein the plurality of micro pores decrease in size based on a temperature change from a first temperature at or higher than a threshold temperature to a second temperature lower than the threshold temperature.

4. The cooling assembly of claim 1, wherein the hydrogel layer comprises a hydrophobic material and a hydrophilic material.

5. The cooling assembly of claim 1, wherein the hydrogel layer comprises a Poly(N-isopropylacrylamide) (PNIPAM) hydrogel.

6. The cooling assembly of claim 1, wherein a lower critical solution temperature (LCST) of the hydrogel layer is about 25-80 degrees Celsius (° C.).

7. The cooling assembly of claim 1, wherein the manifold is thermally conductive.

8. An electronic assembly, comprising:
an electronic device; and
a cooling assembly for cooling the electronic device, the cooling assembly comprising:
a hydrogel layer on a thermally conductive substrate, the hydrogel layer comprising a plurality of macro pores and a micro pore region comprising a plurality of micro pores;
a manifold comprising:
one or more liquid inlet ports;
a liquid channel operable for receiving a cooling liquid through the one or more liquid inlet ports; and
a plurality of liquid outlets operable for transporting the cooling liquid from the liquid channel to the hydrogel layer; and
a vapor chamber positioned between the thermally conductive substrate and the manifold, the vapor chamber comprising one or more vapor outlet ports and operable for transporting vapor from the plurality of macro pores on the hydrogel layer to the one or more vapor outlet ports; and
wherein the plurality of micro pores change in size based on temperature.

9. The electronic assembly of claim 8, wherein the plurality of micro pores increase in size based on a temperature change from a first temperature lower than a threshold temperature to a second temperature at or higher than the threshold temperature.

10. The electronic assembly of claim 8, wherein the plurality of micro pores decrease in size based on a temperature change from a first temperature at or higher than a threshold temperature to a second temperature lower than the threshold temperature.

11. The electronic assembly of claim 8, wherein the hydrogel layer comprises a hydrophobic material and a hydrophilic material.

12. The electronic assembly of claim 8, wherein the hydrogel layer comprises a Poly(N-isopropylacrylamide) (PNIPAM) hydrogel.

13. The electronic assembly of claim 8, wherein a lower critical solution temperature (LCST) of the hydrogel layer is about 25-80 degrees Celsius (° C.).

14. The electronic assembly of claim 8, further comprising:
a pump coupled to the one or more liquid inlet ports via one or more corresponding liquid inlet lines, the pump configured to pump the cooling liquid from a reservoir towards the one or more liquid inlet ports; and
a condenser coupled to the one or more vapor outlet ports via one or more corresponding vapor outlet lines, the condenser configured to:
receive the vapor from the vapor chamber; and
condense the vapor into a liquid to be transported to the reservoir.

15. A vehicle, comprising:
an electric motor; and
an electronic assembly comprising an electronic device and a cooling assembly for cooling the electronic device, wherein the cooling assembly comprises:
a hydrogel layer on a thermally conductive substrate, the hydrogel layer comprising a plurality of macro pores and a micro pore region comprising a plurality of micro pores;
a manifold comprising:
one or more liquid inlet ports;
a liquid channel operable for receiving the cooling liquid through the one or more liquid inlet ports; and
a plurality of liquid outlets operable for transporting the cooling liquid from the liquid channel to the hydrogel layer; and
a vapor chamber positioned between the thermally conductive substrate and the manifold, the vapor chamber comprising one or more vapor outlet ports and operable for transporting vapor from the plurality of macro pores on the hydrogel layer to the one or more vapor outlet ports; and
wherein the plurality of micro pores change in size based on temperature.

16. The vehicle of claim 15, wherein the plurality of micro pores increase in size based on a temperature change from a first temperature lower than a threshold temperature to a second temperature at or higher than the threshold temperature.

17. The vehicle of claim 15, wherein the plurality of micro pores decrease in size based on a temperature change from a first temperature at or higher than a threshold temperature to a second temperature lower than the threshold temperature.

18. The vehicle of claim 15, wherein the hydrogel layer comprises a hydrophobic material and a hydrophilic material.

19. The vehicle of claim 15, wherein the hydrogel layer comprises a Poly(N-isopropylacrylamide) (PNIPAM) hydrogel.

20. The vehicle of claim 15, wherein a lower critical solution temperature (LCST) of the hydrogel layer is about 25-80 degrees Celsius (° C.).
